(19) United States
(12) Patent Application Publication
(10) Pub. No.: US 2026/0018424 A1
(43) Pub. Date: Jan. 15, 2026

(54) METHOD OF MANUFACTURING SEMICONDUCTOR PACKAGES

(71) Applicant: Samsung Electronics Co., Ltd., Suwon-si (KR)

(72) Inventor: Chulho Jung, Suwon-si (KR)

(21) Appl. No.: 19/221,991

(22) Filed: May 29, 2025

(30) Foreign Application Priority Data
Jul. 11, 2024 (KR) 10-2024-0091496

(51) Int. Cl. H01L 21/48; H01L 21/56; H01L 21/683

(52) U.S. Cl. CPC H01L 21/4846; H01L 21/568; H01L 21/6836; H01L 2221/68327; H01L 2221/68359

(57) ABSTRACT

Provided is a method of manufacturing a semiconductor package, the method including: forming a bonding layer on a carrier, forming a redistribution substrate on the bonding layer, mounting a plurality of semiconductor chips on the redistribution substrate, forming a package structure for a plurality of semiconductor packages; bonding an ultraviolet (UV)-curable adhesive sheet to a surface of the package structure opposite the bonding layer and redistribution substrate; separating or removing the carrier and the bonding layer from the package structure; forming an under bump metallurgy (UBM) layer and forming an external connection conductor on the redistribution substrate; cutting the package structure into the plurality of semiconductor packages; irradiating the UV-curable adhesive sheet with UV rays, after cutting the plurality of semiconductor packages; and separating the plurality of semiconductor packages from the UV-curable adhesive sheet.

### CROSS-REFERENCE TO RELATED APPLICATION(S)

This U.S. non-provisional application claims benefit of priority to Korean Patent Application No. 10-2024-0091496, filed on Jul. 11, 2024, the inventive concept of which is incorporated herein by reference in its entirety.

### BACKGROUND

The present inventive concept relates to a method of manufacturing a semiconductor package.

Recently, demand for portable devices has rapidly increased in the market of electronic products, and thus, demand for miniaturization and weight reduction of electronic components installed in such products, is continuously required. In order to miniaturize and reduce the weight of electronic components, a degree of integration of semiconductor devices used in electronic components is also required.

Various semiconductor packaging technologies are being actively researched to improve the scaling and degree of integration of electronic components. In particular, undesired deformation may occur on a curable adhesive sheet due to manufacturing process environments (e.g., plasma chemical etching process), which may deteriorate the reliability of the semiconductor package.

### SUMMARY

An aspect of the present inventive concept is to provide a method of manufacturing a semiconductor package having improved yield.

According to an aspect of the present inventive concept, provided is a method of manufacturing a semiconductor package, the method including: forming a bonding layer on a carrier; forming a redistribution substrate on the bonding layer; mounting a plurality of semiconductor chips on the redistribution substrate, forming a package structure for a plurality of semiconductor packages; bonding an ultraviolet (UV)-curable adhesive sheet to a surface of the package structure opposite the bonding layer and redistribution substrate; separating or removing the carrier and the bonding layer from the package structure; forming an under bump metallurgy (UBM) layer and an external connection conductor on the redistribution substrate; cutting the package structure into the plurality of semiconductor packages; irradiating the UV-curable adhesive sheet with UV rays, after cutting the plurality of semiconductor packages; and separating the plurality of semiconductor packages from the UV-curable adhesive sheet.

According to an aspect of the present inventive concept, provided is a method of manufacturing a semiconductor package, the method including: forming a bonding layer on a carrier, wherein the bonding layer includes a release layer on the carrier and a metal layer on the release layer; forming a redistribution substrate on the bonding layer; mounting a plurality of semiconductor chips on the redistribution substrate, forming a package structure for a plurality of semiconductor packages; bonding an ultraviolet (UV)-curable adhesive sheet to a surface of the package structure opposite the bonding layer and redistribution substrate, wherein the UV-curable adhesive sheet includes an adhesive composition including a polymer, a monomer, and a photoinitiator, the monomer including a monomer branched into the polymer; separating the carrier from the package structure using the release layer; removing the metal layer from the package structure using wet etching; forming an under bump metallurgy (UBM) layer on the redistribution substrate; forming an external connection conductor on the UBM layer, and applying a reflow process to the external connection conductor; cutting the package structure into the plurality of semiconductor packages; irradiating the UV-curable adhesive sheet with UV rays, after cutting the plurality of semiconductor packages; and separating the plurality of semiconductor packages from the UV-curable adhesive sheet.

According to an aspect of the present inventive concept, provided is a method of manufacturing a semiconductor package, the method including: forming a bonding layer on a carrier, wherein the bonding layer includes a release layer on the carrier and a metal layer on the release layer; forming a redistribution substrate on the bonding layer; mounting a plurality of semiconductor chips on the redistribution substrate, forming a package structure for a plurality of semiconductor packages; bonding an ultraviolet (UV)-curable adhesive sheet to a surface of the package structure opposite the bonding layer and redistribution substrate, wherein an adhesive composition of the UV-curable adhesive sheet includes a photoinitiator having thermal stability so that 90% or more of an initial weight of the photoinitiator is maintained for 10 minutes at 200° C. or higher; separating the carrier from the package structure using the release layer; removing the metal layer from the package structure using wet etching; forming an under bump metallurgy (UBM) layer on the redistribution substrate; forming an external connection conductor on the UBM layer, and applying a reflow process to the external connection conductor; cutting the package structure into the plurality of semiconductor packages; irradiating the UV-curable adhesive sheet with UV rays, after cutting the plurality of semiconductor packages; and separating the plurality of semiconductor packages from the UV-curable adhesive sheet, wherein the UV-curable adhesive sheet has a first adhesive strength before the reflow process, has a second adhesive strength higher than the first adhesive strength after the reflow process and before the irradiating the UV-curable adhesive sheet with UV rays, and a third adhesive strength lower than the first adhesive strength after the irradiating the UV-curable adhesive sheet with UV rays.

### BRIEF DESCRIPTION OF DRAWINGS

The above and other aspects, features, and advantages of the present disclosure will be more clearly understood from the following detailed description, taken in conjunction with the accompanying drawings:

FIGS. 1 and 2 are flowcharts illustrating a method of manufacturing a semiconductor package according to an example embodiment of the present inventive concept;

FIGS. 3A to 3E are cross-sectional views of major processes illustrating some processes in a method of manufacturing a semiconductor package according to an example embodiment of the present inventive concept;

FIGS. 4A to 4F are cross-sectional views of major processes illustrating some other processes in a method of manufacturing a semiconductor package according to an example embodiment of the present inventive concept;

FIG. 5 is a side cross-sectional view illustrating a UV curing adhesive sheet employed in a method of manufacturing a semiconductor package according to an example embodiment of the present inventive concept;

FIG. 6 is a schematic diagram for illustrating an adhesive composition employed in a UV-curable adhesive sheet according to an example embodiment of the present inventive concept;

FIG. 7 is a TGA (Thermo-Gravimetric Analysis) graph of a photoinitiator employed in an example embodiment of the present inventive concept;

FIGS. 8A and 8B are schematic diagrams for illustrating a UV curing process within the UV-curable adhesive sheet;

FIG. 9 is a graph illustrating a change in adhesive strength of the UV-curable adhesive sheet in a process of manufacturing a semiconductor package;

FIG. 10 is a cross-sectional view illustrating a semiconductor package according to an example embodiment of the present inventive concept; and

FIGS. 11A to 11G are cross-sectional views of major processes illustrating a method of manufacturing a semiconductor package according to an example embodiment of the present inventive concept.

### DETAILED DESCRIPTION

Hereinafter, various embodiments of the present inventive concept will be described in detail with reference to the attached drawings.

The invention may be embodied in many different forms and should not be construed as limited to the example embodiments set forth herein. These example embodiments are just that—examples—and many implementations and variations are possible that do not require the details provided herein. The disclosure provides details of alternative examples, but such listing of alternatives is not exhaustive.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim

Spatially relative terms, such as “upper,” “lower”, “vertical”, and the like, may be used herein for ease of description to describe positional relationships, such as illustrated in the figures, for example. It will be understood that the spatially relative terms encompass different orientations, in addition to the orientation depicted in the figures.

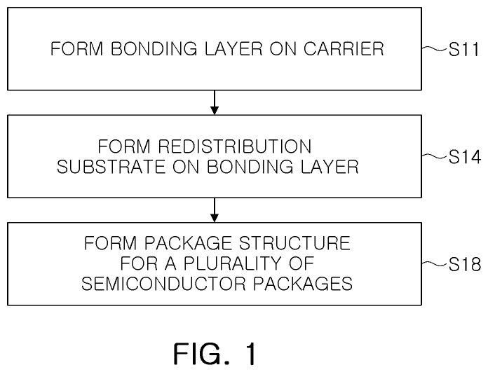

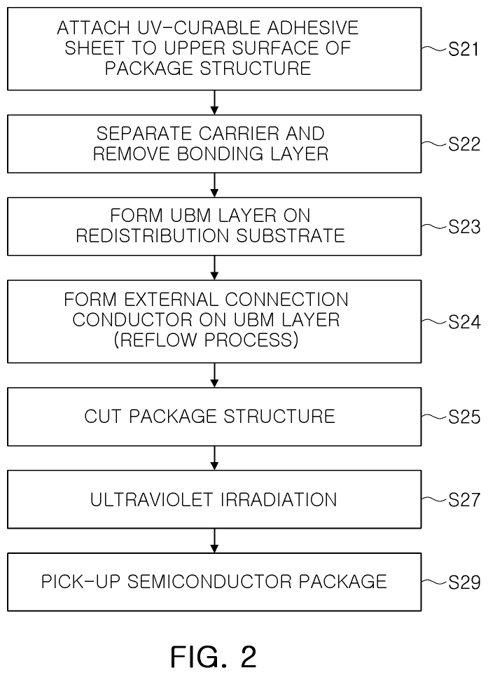

FIGS. 1 and 2 are flowcharts illustrating a method of manufacturing a semiconductor package according to an example embodiment of the present inventive concept. FIG. 1 is a flowchart illustrating a manufacturing process of a package structure for forming a plurality of semiconductor packages, and FIG. 2 is a flowchart illustrating subsequent processes such as forming an external connection conductor in the package structure and cutting a semiconductor package.

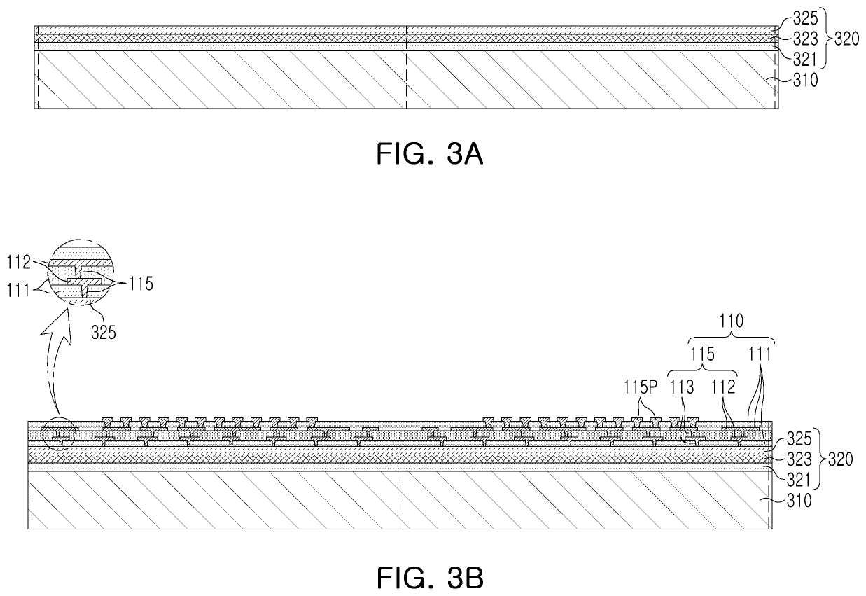

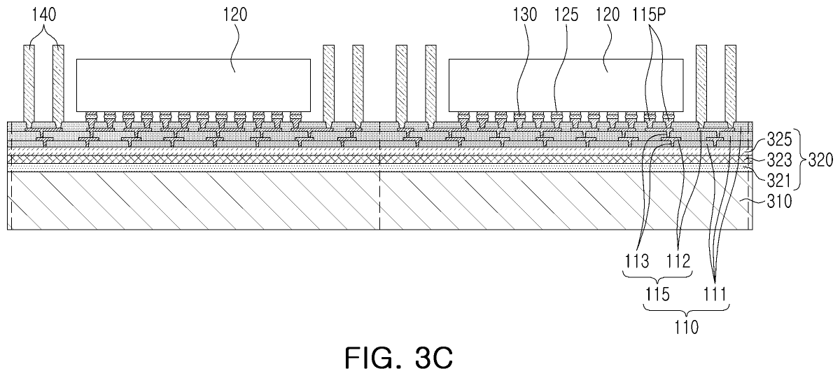

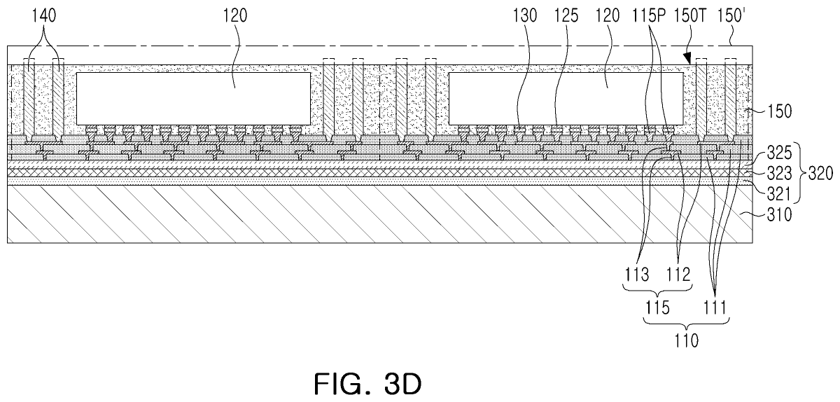

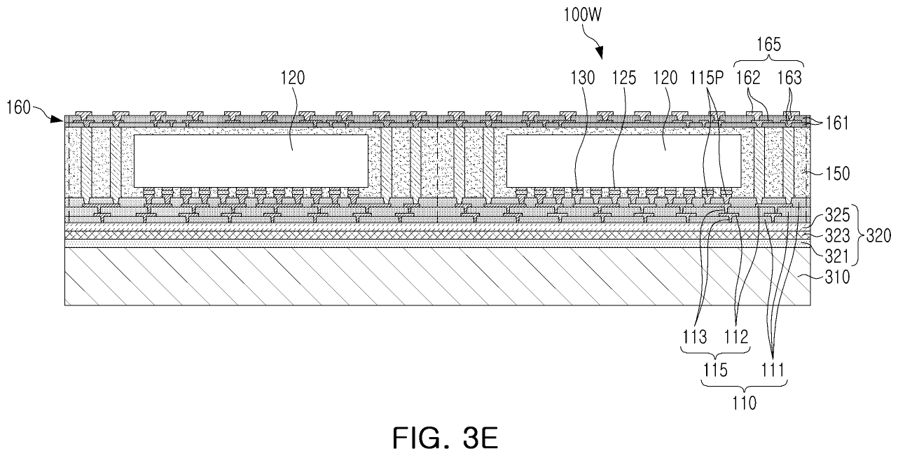

First, examples of a manufacturing process of the exemplary package of FIG. 1 may be described with reference to the cross-sectional views of major process of FIGS. 3A to 3E.

Referring to FIG. 3A together with FIG. 1, the manufacturing method according to the present embodiment may begin with a process of forming a bonding layer 320 on a carrier 310 (S11).

The bonding layer 320 employed in the present embodiment may include metal layers 323 and 325 in addition to a release layer 321. In an example embodiment, the metal layers may include a barrier metal layer 323 and a seed layer 325. Specifically, as illustrated in FIG. 3A, a release layer 321, a barrier metal layer 323, and a metal seed layer 325 may be sequentially formed on the carrier 310.

For example, the carrier 310 may include a glass substrate or a ceramic substrate. The release layer 321 may include a light-to-heat-conversion (LTHC) material, and may be formed on the carrier 310. In some example embodiments, LTHC material may be decomposed by energy light such as a laser, thereby separating a structure bonded thereon from the carrier 310. For example, the barrier metal layer 323 may include titanium or an alloy thereof, and the metal seed layer 325 may include copper (Cu). For example, the barrier metal layer 323 and the metal seed layer 325 may be formed by a sputtering process. The metal seed layer 325 may be used in a plating process to form a subsequent redistribution layer (115 in FIG. 3B).

Next, referring to FIGS. 1 and 3B, a redistribution substrate 110 may be formed on the bonding layer 320 (S14).

The present process includes a process of forming an insulating film (111) on the metal seed layer 325 using a lamination or coating method (e.g., spin coating), a process of forming a hole in the insulating film 111, and a process of forming a redistribution layer 115 using a plating process such as electrolytic plating. By repeating such a series of processes, a desired layer of redistribution substrate 110 may be formed. Each redistribution layer 115 may include a corresponding redistribution pattern 112 forming a two-dimensional redistribution circuit pattern on an insulating layer 111 and a redistribution via 113 for interlayer connection through a hole in the insulating layer 111. An uppermost redistribution layer disposed in a chip mounting region may be provided as contact pads 115P. The contact pads 115P may be connected to corresponding chip pads 125 of a semiconductor chip 120 in a subsequent process (see FIG. 3C).

For example, the insulating film 111 may use a photosensitive insulating material (PID), and in this case, the hole may be formed at a finer pitch using a photolithography method. The redistribution layer 115 may include, for example, Cu, and the redistribution pattern 112 and the redistribution via 113 may be formed to have an integrated structure through a plating process. The redistribution substrate 110 employed in the present embodiment may be formed by the build-up process described herein, and the redistribution via 113 may have a tapered structure to be narrower toward a lower surface of the redistribution substrate 110.

Next, a package structure for a plurality of semiconductor packages may be formed on the redistribution substrate 110 (S18).

The redistribution substrate 110 formed in the previous process may be divided into a plurality of package regions (indicated by dotted lines).

A package structure to be formed in the present process may include a plurality of semiconductor packages 100, having at least one semiconductor chip 120 in a package region. A process of forming an exemplary package structure (100W in FIG. 3E) may be illustrated in FIGS. 3C to 3E.

First, referring to FIG. 3C, conductive posts 140 may be formed around a chip mounting region on the redistribution substrate 110, and a semiconductor chip 120 may be mounted on the chip mounting region.

The conductive posts 140 may be provided as vertical connection conductors connected to the redistribution layer 115. In the present embodiment, the conductive posts 140 may be formed using a plating process from an open region of the redistribution pattern 112. The plating process may be an electroplating or electroless plating process. The conductive posts 140 may be formed to a height greater than the final height, considering a subsequent planarizing process. The conductive posts 140 may have various arrangements, and may also be implemented as vertical connection conductors of various other structures connecting a lower redistribution layer (e.g., 115) and an upper redistribution layer (e.g., 165 in FIG. 3E). In some example embodiments, the vertical connection conductor may include a block body (e.g., a multilayer insulating layer) such as a frame and a wiring structure (e.g., a multilayer wiring layer) connecting upper and lower surfaces of the block body. Each chip pad 125 of a semiconductor chip 120 mounted on a chip mounting region may be connected to a corresponding contact pad 115P by a corresponding conductive bump 130 such as a micro bump.

Subsequently, referring to FIG. 3D, after forming a pre-planarized encapsulant 150′, the encapsulant 150′ may be planarized, yielding the first encapsulant 150. The conductive posts 140 may be exposed on a planarized upper surface 150T of the first encapsulant 150.

A pre-planarized encapsulant 150′ covering the semiconductor chip 120 and the conductive posts 140 is formed using a molding resin. The encapsulant 150′ may have a sufficient thickness to cover the semiconductor chip 120 and conductive posts 140. Next, a planarizing process such as grinding can be performed on an upper surface of the pre-planarized encapsulant 150′. The first encapsulant 150 has a planarized upper surface 150T, and the conductive posts 140 may be exposed through the planarized upper surface 150T. As described herein, the exposed surfaces of the conductive posts 140 may be substantially coplanar with the upper surface 150T of the first encapsulant 150. By such a planarizing process, the upper surface 150T of the first encapsulant 150 may provide advantageous conditions for forming a redistribution structure (160 in FIG. 3E).

Next, referring to FIG. 3E, a redistribution structure 160 may be formed on the planarized upper surface 150T of the first encapsulant 150.

A process of forming the redistribution structure 160 may be performed similarly to the process of forming the redistribution substrate 110. Specifically, the present process includes a process of forming an insulating film 161 and a process of forming an upper redistribution layer 165, and by repeating such a series of processes, a redistribution substrate 110 having a desired number of layers may be formed. Each upper redistribution layer 165 may include a corresponding redistribution pattern 162 and a corresponding redistribution via 163. An uppermost redistribution layer disposed in the chip mounting region may be provided with contact pads.

The redistribution structure 160 employed in the present embodiment is formed by the build-up process described herein, and similar to the redistribution substrate 110, the redistribution via 163 may have a tapered structure so as to narrow toward the redistribution substrate 110.

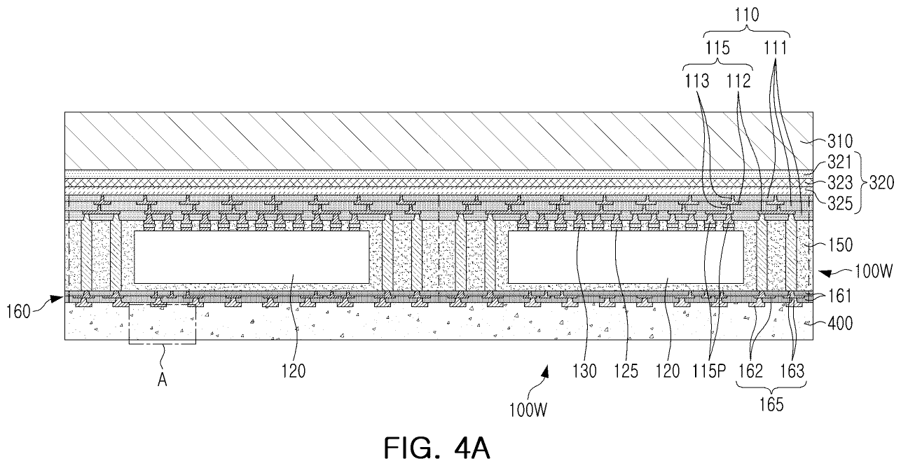

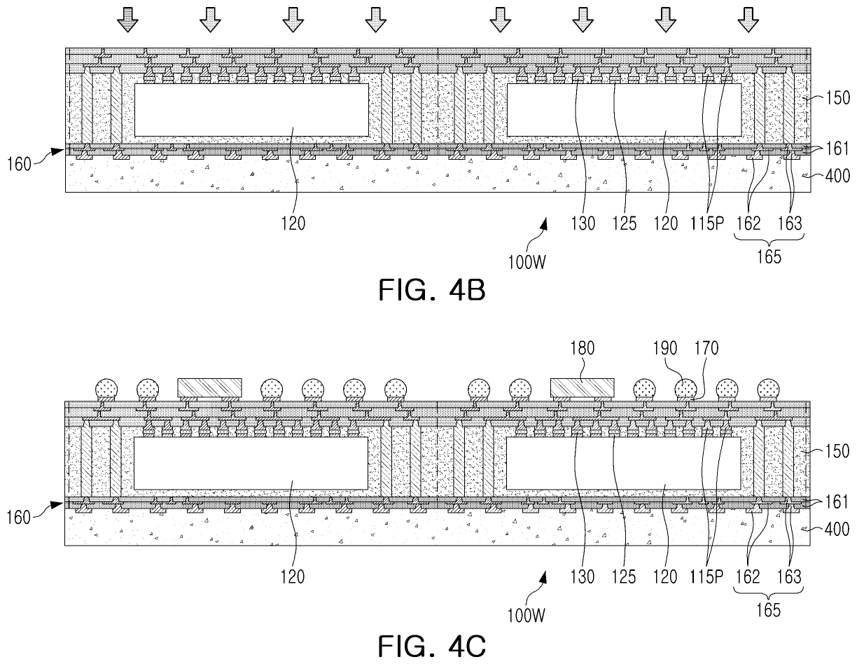

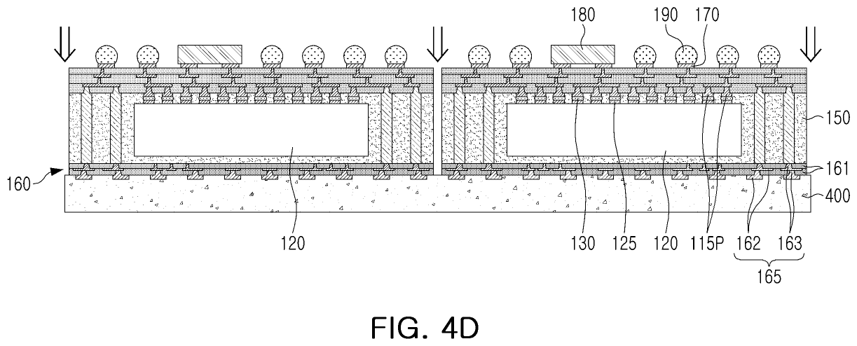

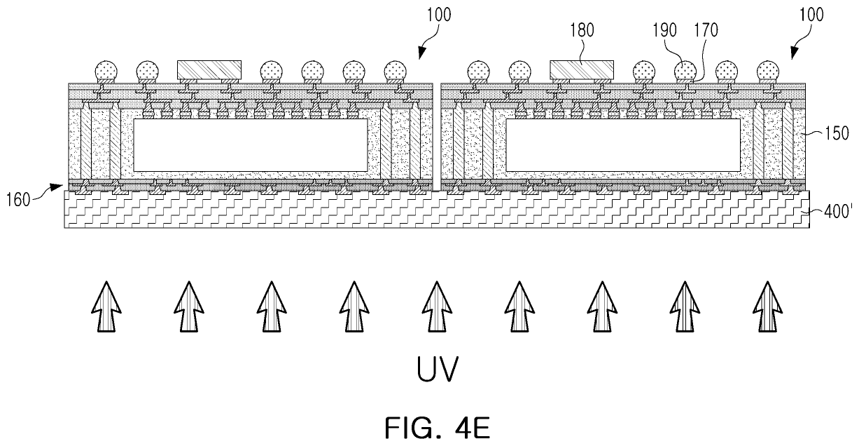

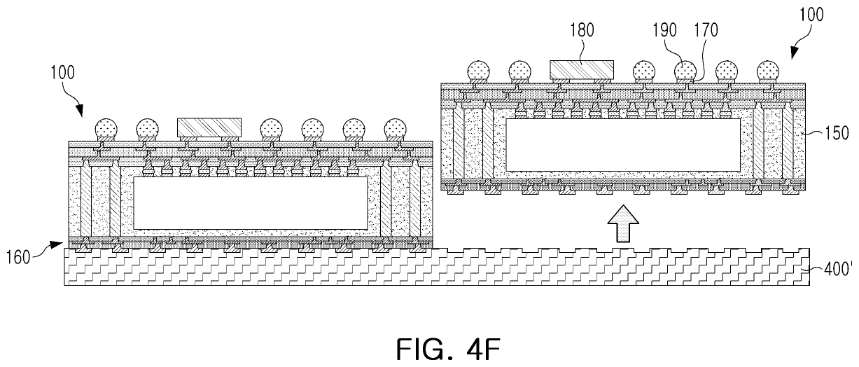

FIG. 2 is a flowchart illustrating subsequent processes including forming an external connection conductor in a package structure and cutting a semiconductor package, and the exemplary manufacturing process of FIG. 2 may be described with reference to the cross-sectional views of major process of FIGS. 4A to 4F.

Referring to FIG. 4A together with FIG. 2, an ultraviolet (UV)-curable adhesive sheet 400 may be attached to an upper surface of a package structure 100W (S21).

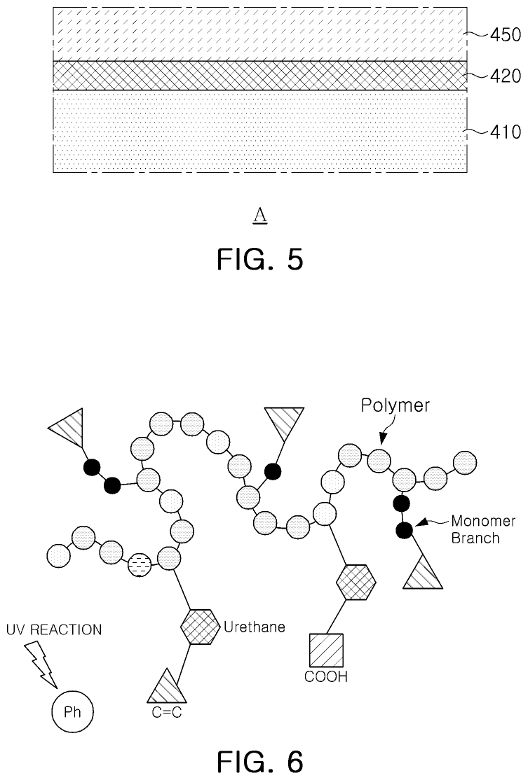

The upper surface of the package structure 100W in a state in which a carrier 300 is attached thereto may be disposed on the package structure 100W so as to be adhered to the UV-curable adhesive sheet 400. The UV-curable adhesive sheet 400 may include a UV-curable adhesive layer having an adhesive composition on the adhesive surface. Initial adhesive strength of the UV-curable adhesive layer may be used to adhere to the upper surface of the package structure. FIG. 5 is a cross-sectional side view illustrating portion (“A”) of the UV-curable adhesive sheet 400 employed in the process according to the present embodiment.

Referring to FIG. 5, the UV-curable adhesive sheet 400 may include a base film 410 and a UV-curable adhesive layer 450 on the base film 410. In the present embodiment, an anchor layer 420 between the base film 410 and the UV-curable adhesive layer 450 may be further included.

The base film 410 may be provided in a sheet structure including, for example, at least one material selected from the group consisting of polyether ether ketone (PEEK), polyethylene naphthalate (PEN), and polyethylenimine (PEI), or aramid.

The UV-curable adhesive layer 450 may include a pressure-sensitive adhesive (PSA) having a UV-curable system. For example, the UV-curable adhesive layer 450 may include a photoinitiator operating on UV rays, together with a polymer and a monomer such as acrylate, silicone, and imide-based materials. In some example embodiments, the UV-curable adhesive layer 450 may include an acrylic-based polymer, an acrylic-based monomer having a carbon-carbon bond, and a photoinitiator having an operating wavelength of 460 nm or less, or for example, having an operating wavelength of 250 nm to 460 nm. In some example embodiments, the photoinitiator may have an operating wavelength of 410 nm or less.

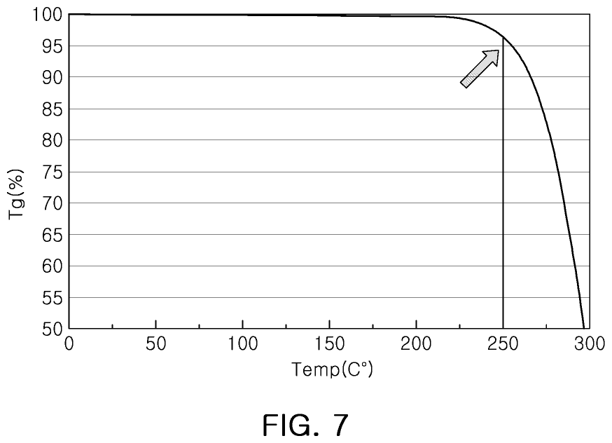

The UV-curable adhesive layer 450 employed in the present embodiment may include an adhesive composition having improved chemical resistance to suppress monomer elution in a subsequent wet etching process. The adhesive composition may include a monomer branched into the polymer. In addition, the adhesive composition may further include an oligomer in which at least a portion of the monomers are cross-linked to each other. This will be described herein with reference to FIGS. 4B and 6. The photoinitiator employed in the present embodiment may have high thermal stability so as not to be thermally decomposed during the reflow process. This will be described herein with reference to FIGS. 4C and 7.

Next, referring to FIG. 4B together with FIG. 2, a process of separating/removing a carrier 310 and a bonding layer 320 from the package structure 100W may be performed (S22).

The present process may be performed by the process of separating the carrier 310 and a process of removing a barrier metal layer 323 and a metal seed layer 325. The separation of the carrier 310 may be performed by applying energy such as a laser to a release layer 321 to decompose the release layer 321.

Next, the removal of the barrier metal layer 323 and the metal seed layer 335 may be performed by a plasma and/or wet etching process. For example, the barrier metal layer 323, Ti and/or the metal seed layer 325, Cu may be removed by wet etching using a KOH+H₂O₂ etchant.

In wet etching, an uncured UV-curable adhesive sheet may be eluted with a low molecular weight monomer due to a chemical reaction with an etchant, which may cause voids to be generated in the UV-curable adhesive sheet or the package structure to be peeled off. Therefore, in prior methods, the problem of monomer elution has been addressed by curing the UV-curable adhesive sheet by radiating UV rays immediately after the process of attaching UV-curable adhesive sheet or before other steps are performed.

In contrast, in the present embodiments, rather than curing the UV-curable adhesive sheet 400 in a previous process, such as immediately after the process of attaching a UV-curable adhesive sheet or before performing further steps, the present methods are provided to enhance chemical resistance of the UV-curable adhesive sheet 400, and to maintain high adhesive strength of the UV-curable adhesive sheet until the cutting process (see FIG. 4D). According to example embodiments, in the present methods, UV rays are not radiated immediately after attaching a UV-curable adhesive sheet, or after attaching a UV-curable adhesive sheet and before performing other steps. As described herein, example embodiments include a method to suppress monomer elution during wet etching by combining monomers of an uncured UV-curable adhesive sheet 400 in various forms to increase the molecular weight.

FIG. 6 is a schematic diagram illustrating an adhesive composition employed in a UV-curable adhesive sheet according to an example embodiment of the present inventive concept.

Referring to FIG. 6, together with a photoinitiator (Ph), at least a portion of monomers may be branched into a polymer. The monomer may be branched into the polymer by hydrogen bonding or covalent bonding to suppress elution. In addition, the monomers may further include oligomers which are cross-linked to each other. As described herein, instead of existing as monomers in the uncured adhesive composition, the monomers may be branched into a polymer with a large molecular weight or combined with oligomers having a relatively large molecular weight, so that the monomers may not be easily eluted even during wet etching. The heat resistance of the adhesive composition can be enhanced by reducing a crosslinker such as urethane.

Next, referring to FIG. 4C together with FIG. 1, an under bump metallurgy (UBM) layer 170 and an external connection conductor 190 (e.g., an external connection terminal) may be formed on a surface of the redistribution substrate 110 from which the bonding layer 320 has been removed (S23 and S24).

The UBM layer 170 and the external connection conductor 190 serve to physically and/or electrically connect the semiconductor package to an external circuit, such as a main board of an electronic device. The UBM layer 170 may be formed on the exposed surface of the redistribution substrate 110 to be connected to the lowermost rewiring layer 115 (in particular, the redistribution via 113. The UBM layer 170 may be formed by a sputtering process or a plating process.

An external connection conductor 190 may be formed on each UBM layer 170. After forming an external connection conductor 190 such as a solder bump, a reflow process can be performed. By the reflow process, the external connection conductor 190 may have a ball shape while being fixed to the UBM layer 170. For example, the external connecting conductor 190 may include solder containing tin (Sn) or an alloy containing tin (Sn) (Sn—Ag—Cu). Such a reflow process may be performed at a temperature of 200° C. or higher, for example, 250° C. or higher, for several minutes. The relatively high temperature reflow process can cause a problem in which the photoinitiator is thermally decomposed in the uncured UV curable adhesive sheet 400. This can significantly degrade the UV curing system. However, in the present embodiment, by maintaining the high adhesive strength of the UV-curable adhesive sheet until the cutting process (see FIG. 4D) and then curing the UV-curable adhesive sheet 400 before the pick-up process (see FIG. 4F), defects in the pick-up process can be effectively prevented. To this end, the UV-curable adhesive sheet 400 uses a photoinitiator with excellent thermal stability.

In some example embodiments, the UV-curable adhesive sheet 400 may include a urethane having carbon-carbon bonds (C═C bonding), but because such urethane is relatively susceptible to thermal decomposition, at least a portion or all of the urethane may be replaced with an ester having relatively strong thermal stability.

FIG. 7 is a Thermo-Gravimetric Analysis (TGA) graph of a photoinitiator employed in an example embodiment of the present inventive concept.

Referring to FIG. 7, thermal stability of the photoinitiator employed in the present embodiment is indicated by a weight ratio, which is thermally decomposed with increasing temperature. For example, the photoinitiator employed in the present embodiments may maintain 90% or more of a weight of the photoinitiator for 10 minutes at 200° C. or 200° C. or higher, and further can maintain 95% or more of the weight for 10 minutes at 250° C., or 250° C. or higher. According to example embodiments, the photoinitiator has a thermal stability such that it may maintain a weight of 90-100% for 10-30 minutes at 200° C.-300° C. Thus, because the photoinitiator employed in the present embodiment has thermal stability that minimizes thermal decomposition under reflow conditions, an ultraviolet (UV) curing system may be maintained even after the reflow process, and the adhesive strength may be reduced by curing at a desired time (e.g., see FIG. 4E).

In the present embodiment, a surface mounting device 180 may be mounted on a portion of the UBM layer of the redistribution substrate. The surface mounting device 180 may be a passive device such as a capacitor chip.

Next, referring to FIG. 4D together with FIG. 1, the package structure 100W may be cut into individual semiconductor packages 100 (S25).

Even in the present process, because the UV-curable adhesive sheet 400 is in an uncured state, the UV-curable adhesive sheet 400 has high adhesive strength, and can stably maintain the package structure 100W. In particular, the adhesive strength can be further increased by increasing anchoring of the adhesive composition of the UV-curable adhesive sheet under the high temperature conditions of the previous reflow process.

As in the prior art, in order to solve the problem of elution due to the problem of wet etching, when the UV-curable adhesive sheet 400 is pre-cured, the adhesive strength is low in the cutting process, so a “flying” defect, in which the semiconductor package being cut suddenly flies away, may occur. On the other hand, in the present embodiment, because the UV-curable adhesive sheet 400 is maintained in an uncured state, “flying” defects can be effectively prevented.

Next, referring to FIG. 4E, ultraviolet rays (UV) may be radiated to the UV-curable adhesive sheet 400 (S27).

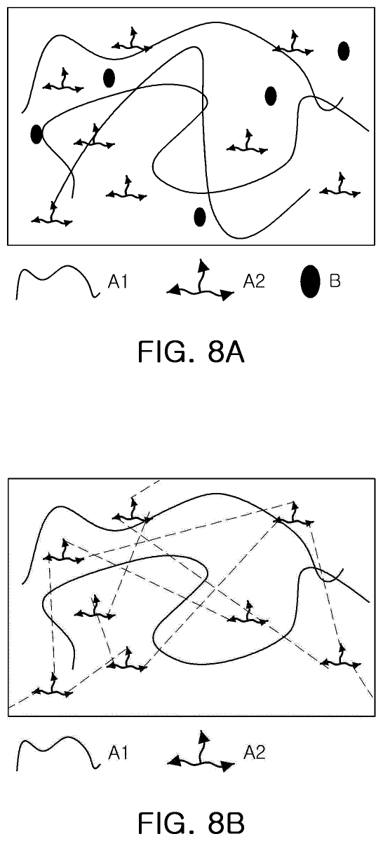

The UV-curable adhesive sheet 400 includes an adhesive composition having a UV-curable system, and may be cured by UV rays in the present process. FIGS. 8A and 8B are schematic diagrams for illustrating a UV curing process within a UV curing adhesive sheet.

Referring to FIG. 8A, an uncured adhesive composition is illustrated. The adhesive composition may include a photoinitiator (B) operating on UV rays, together with a polymer (A1) and a monomer (B1). In some example embodiments, the adhesive composition may include an acrylic-based polymer, an acrylic-based monomer having a carbon-carbon bond, and a photoinitiator having an operating wavelength of 460 nm or less. In example embodiments, the polymer and monomer may be an acrylate. In example embodiments, the polymer and monomer may have a thermal decomposition temperature of 180° C. or higher, such as 180° C. to 250° C.

After irradiation of the UV-curable adhesive sheet with ultraviolet light (e.g., 405 nm), as shown in FIG. 8B, the photoinitiator (B) may absorb ultraviolet light and decompose, so that a monomer (A2) (or oligomer) may react with reactive species to be connected to each other (as indicated by a dotted line) to additionally form a long-chain of monomer. As the chain is longer, the viscosity increases, and may be finally cured. The adhesive strength of the cured UV-curable adhesive sheet 400 may be significantly reduced.

As a result thereof, referring to FIGS. 1 and 4F, the semiconductor package 100 cut from the cured UV-curable adhesive sheet 400 may be easily picked up (S29). In addition, in the present embodiment, because the UV-curable adhesive sheet 400 can be significantly lowered in the present step, defects such as breakage of the semiconductor package 100 that occur when the adhesive strength remaining during the pick-up process is high may also be prevented.

As described herein, in the method of manufacturing a semiconductor package according to the present embodiment, a manufacturing process of a high-yield semiconductor package can be secured, by changing a UV radiation time of the UV-curable adhesive sheet, and enhancing chemical resistance and/or heat resistance of the adhesive composition. The method of manufacturing a semiconductor package according to the present embodiment can be described by the change in adhesive strength as the process progresses.

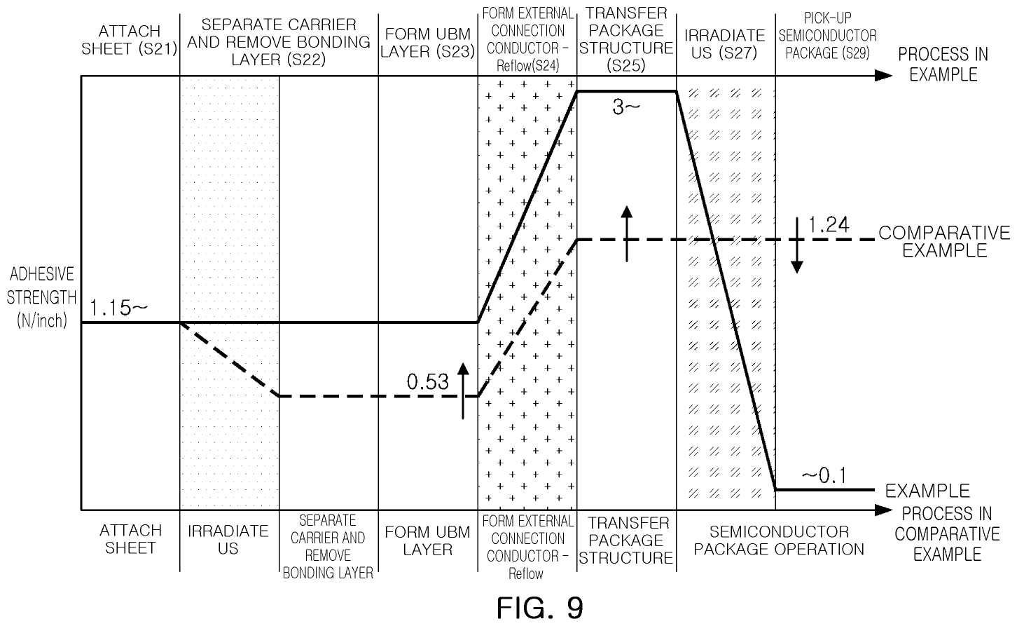

FIG. 9 is a graph illustrating changes in an adhesive strength of a UV-curable adhesive sheet in a semiconductor package manufacturing process.

In a Comparative Example, after attaching a package structure to a UV-curable adhesive sheet, there is a change in adhesive strength in a process in which the UV-curable adhesive sheet is irradiated with UV rays and is partially cured after the package structure is attached to the UV-curable adhesive sheet. In contrast, in the present examples, as described herein, a UV-curable adhesive sheet 400 is irradiated with UV rays after cutting the package structure 100 (see FIG. 4D) and before pick-up of the semiconductor package (see FIG. 4F). In the present examples there is a change in adhesive strength 0 by radiating the UV-curable adhesive sheet 400 with UV rays, as illustrated in FIG. 4E, with the UV-curable sheet upon irradiation 400′ being shown.

First, referring to Comparative Example in FIG. 9, after attaching the package structure to a UV-curable adhesive sheet having an initial adhesive strength (e.g., 1.15), the adhesive strength (e.g., 0.53) is lowered by irradiating the same with UV rays. However, because the UV-curable adhesive sheet is cured in advance, the monomer elution may be suppressed in a process of removing the adhesive layer (see FIG. 4B). In a high-temperature reflow process, the UV-curable adhesive sheet has a somewhat increased adhesive strength due to an anchoring action of the adhesive composition, but has insufficient adhesive strength (e.g., 1.24). Therefore, in the cutting process of the package structure (see FIG. 4D), undesirable yield reduction, such as flying defects of the semiconductor package, may occur. In the Comparative Example, as shown in FIG. 9, no UV curing is performed after the initial UV curing.

Because the UV-curable adhesive sheet is already in a cured state, it has a similar adhesive strength to that during the cutting process even during the final pick-up process, and this residual adhesive strength may act as an obstacle to the smooth performance of the pick-up process.

On the other hand, referring to the example embodiment of FIG. 9, the UV-curable adhesive sheet 400 has an initial adhesive strength (hereinafter, referred to as ‘first adhesive strength’), similar to that of the previous Comparative Example (e.g., 1.15), and almost the first adhesive strength may be maintained from the step of separating the carrier and removing the bonding layer (S22) to the step of forming the UBM layer (S23) without ultraviolet curing. In the present embodiment, even if the adhesive layer removal process (see FIG. 4B) is performed in a state in which the UV-curable adhesive sheet is not cured, a molecular weight of the monomer may be increased (branched or forming an oligomer) to suppress the monomer elution.

Next, in the step of forming the external connection conductor (S24) (particularly, the reflow process), the uncured UV-curable adhesive sheet can have a second adhesive strength, greatly increased by an anchoring action of the adhesive composition. The increased second adhesive strength in the uncured state (e.g., 3 or more) may be much greater than the adhesive strength of Comparative Example (e.g., 1.24). In some example embodiments, the second adhesive strength may be at least twice that of the first adhesive strength. Therefore, in the cutting process of the package structure (see FIG. 4D), a sufficient adhesive strength may be provided to prevent defects such as flying defects of the semiconductor package.

Next, by almost completely curing the UV-curable adhesive sheet (see FIG. 4E), after the cutting process (see FIG. 4D), a significantly reduced third adhesive strength (0.1 or less) may be imparted in a final pick-up process (see FIG. 4F). In some example embodiments, the third adhesive strength may be at most 1/10 times that of the first adhesive strength. Such a low third adhesive strength can ensure a smooth pick-up process. In some example embodiments, for smooth process performance, the second adhesive strength may be 2 N/inch or more, and the third adhesive strength may be 1 N/inch or less.

In the present embodiment, even if the uncured UV-curable adhesive sheet is exposed to a high-temperature reflow process, because the photoinitiator has relatively high thermal stability as described herein, the UV-curable adhesive sheet can maintain high UV-curability even after the cutting process.

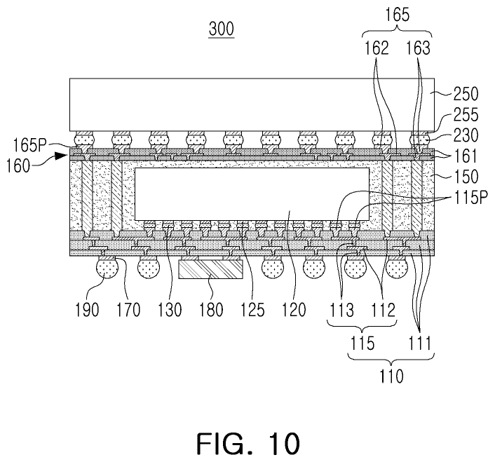

FIG. 10 is a cross-sectional view illustrating a semiconductor package according to an example embodiment of the present inventive concept.

Referring to FIG. 10, a semiconductor package according to the present embodiment has a package on package (POP) structure, and includes a semiconductor package 100 obtained in the process of FIG. 4F and an upper semiconductor chip 250 disposed on the redistribution structure 160 of the semiconductor package 100. Here, the semiconductor package 100 obtained by the manufacturing process according to the present embodiment may be provided as a lower package structure.

As in the previous process, because the external connection conductor 190 of the semiconductor package 100 is not attached to any additional adhesive sheet until pickup, a cleaning process such as plasma is not applied to remove an adhesive resin, remaining on a surface of the external connection conductor 190. When a plasma cleaning process is applied, even if the residual adhesive resin is removed, partial deformation of the external connection conductor 190 may occur, or components of plasma gas (e.g., oxygen) may penetrate a surface region of the external connection conductor 190, but in the external connection conductor 190 according to the present embodiment, such deformation or residues such as oxygen may not be detected.

Some regions of an uppermost redistribution layer 165 among the redistribution structures 160 may be provided as connection pads 165P, and chip pads 255 of the upper semiconductor chip 250 may be connected to the connection pads 165P by conductive bumps 230 such as micro bumps.

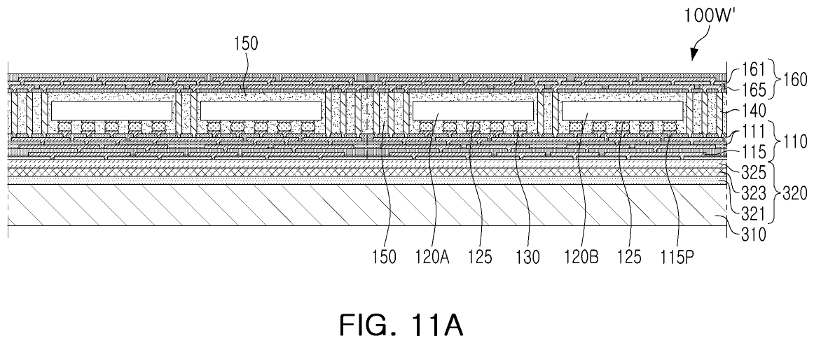

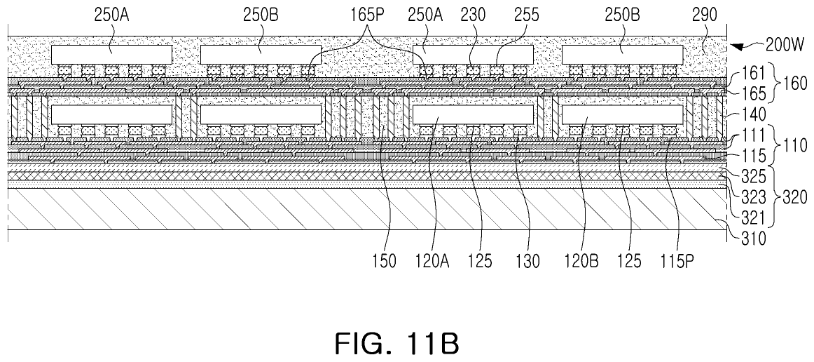

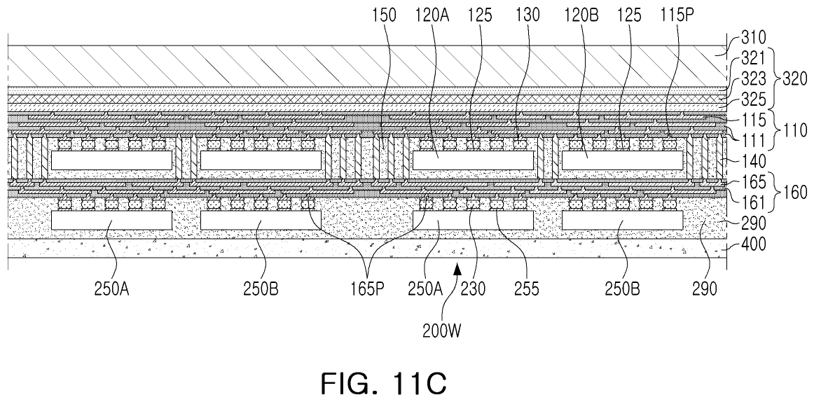

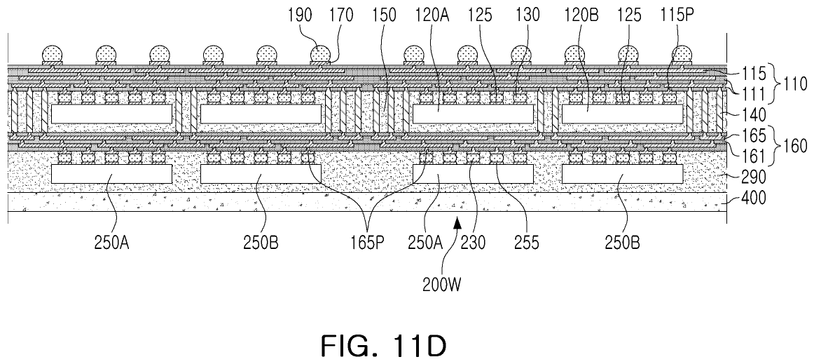

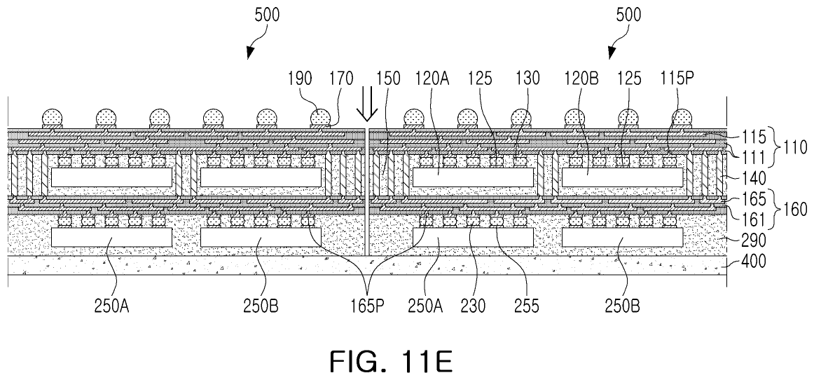

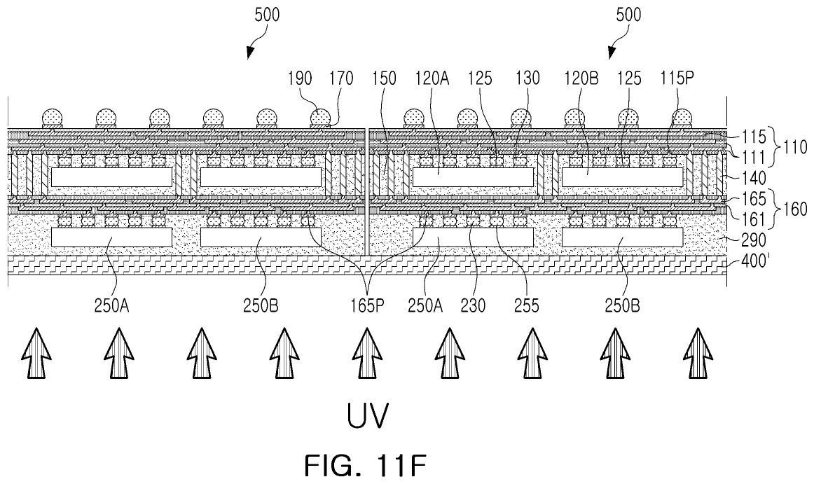

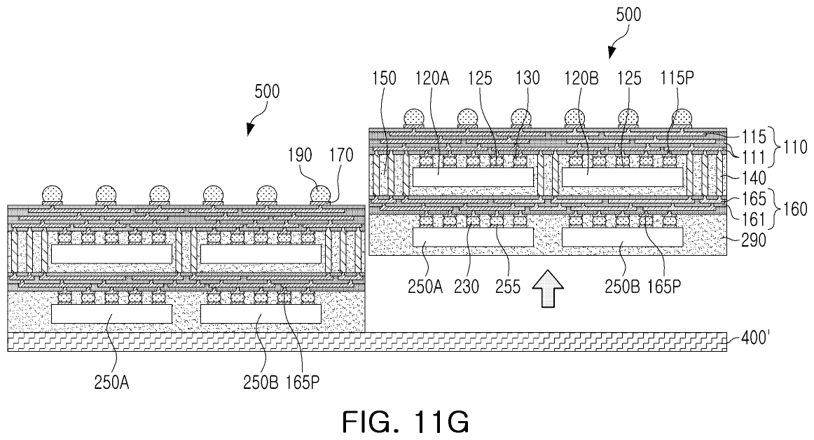

The manufacturing method according to the present embodiment may be advantageously utilized in another manufacturing method of forming a structure for a semiconductor package after forming a redistribution substrate in advance. FIGS. 11A to 11G are cross-sectional views of major processes for illustrating a method of manufacturing a semiconductor package having a POP structure according to an example embodiment of the present inventive concept.

Referring to FIG. 11A, a primary package structure may be formed, similarly to the process illustrated in FIGS. 3A to 3D. However, the primary package structure employed in the present embodiment may include two lower semiconductor chips 120A and 120B disposed in each package region, and conductive posts 140 having a planar arrangement, different from that of the previous embodiment.

First, a bonding layer 320 is formed on a carrier 310. The bonding layer 320 may include a release layer 321, a barrier metal layer 323, and a metal seed layer 325. Next, a redistribution substrate 110 may be formed on the bonding layer 320, and conductive posts 140 and first and second lower semiconductor chips 120A and 120B may be mounted on each package region of the redistribution substrate 110. Each chip pad 125 of the first and second lower semiconductor chips 120A and 120B may be connected to a corresponding contact pad 115P by a corresponding conductive bump 130 such as a micro bump. After forming a pre-planarized encapsulant 150′ to cover the conductive posts 140 and the first and second lower semiconductor chips 120A and 120B on the redistribution substrate 110, the pre-planarized encapsulant 150′ may be planarized until the conductive posts 140 are exposed. Next, a redistribution structure 160 can be formed on the planarized upper surface of the first encapsulant 150. As described herein, a primary package structure corresponding to a lower package structure can be formed. Next, referring to FIG. 11B, first and second upper semiconductor chips 250A and 250B may be mounted on each package region of the redistribution structure 160, and a third encapsulant 290 may be formed to cover the first and second upper semiconductor chips 250A and 250B on the redistribution structure 160. Chip pads 255 of the first and second upper semiconductor chips 250A and 250B may be connected to each of contact pads 165P by conductive bumps 230 such as micro bumps. Thereby, a final package structure 200W may be formed.

Next, referring to FIG. 11C, a UV-curable adhesive sheet 400 may be attached to an upper surface of the package structure 200W.

The upper surface of the package structure 200W in a state in which a carrier attached thereto may be disposed on the package structure 200W so as to be adhered to the UV-curable adhesive sheet 400. The UV-curable adhesive sheet 400 may include a UV-curable adhesive layer having an adhesive composition of an adhesive surface. The UV-curable adhesive layer may include a photoinitiator operating on UV rays, together with polymers and monomers, which may include materials such as acrylate-based, silicone-based, and imide-based materials. The UV-curable adhesive layer employed in the present embodiment may include an adhesive composition having improved chemical resistance to suppress monomer elution in a subsequent wet etching process. The adhesive composition may further include an oligomer in which at least a portion of monomers branched into the polymer and/or monomers are cross-linked to each other. In addition, the photoinitiator employed in this embodiment can have high thermal stability so as not to be thermally decomposed during the reflow process. In examples, the photoinitiator may be a thermal decomposition agent.

Next, referring to FIG. 11D, after separating a carrier 310, and removing a barrier metal layer 323 and a metal seed layer 325 by wet etching, a UBM layer 170 and an external connection conductor 190 may be formed on the exposed surface of the redistribution substrate 110.

In wet etching to remove the barrier metal layer 323 and the metal seed layer 325, an uncured UV-curable adhesive sheet 400 may be eluted with a low molecular weight monomer due to a chemical reaction by an etchant. To suppress such an elution, at least a portion of monomers are branched into a polymer by hydrogen bonds or covalent bonds, and an adhesive composition may further include an oligomer in which monomers are cross-linked to each other. As described herein, instead of existing as monomers in the uncured adhesive composition, the monomers may be branched into a large molecular weight polymer or combined as an oligomer having a relatively large molecular weight, so that they are not easily eluted even during wet etching.

After forming the UBM layer 170 and the external connection conductor 190, a reflow process can be performed on the external connection conductor 190, such as a solder bump. Such a reflow process may be performed at temperatures of 200° C. or higher, for example, at a temperature of 250° C. or higher, or 200° C. -300° C., for several minutes. Thus, because the photoinitiator employed in this embodiment has thermal stability minimizing thermal decomposition under reflow conditions, an ultraviolet curing system can be maintained even after the reflow process, and the adhesive strength may be reduced by curing at a desired time (e.g., see FIG. 11F).

Next, referring to FIG. 11E, a package structure 200W may be cut into individual semiconductor packages 500.

Even in the present process, because a UV-curable adhesive sheet 400 is in an uncured state, the UV-curable adhesive sheet 400 has high adhesive strength and can stably maintain the package structure 200W. In particular, the adhesive strength may be further increased by increasing anchoring of an adhesive composition of the UV-curable adhesive sheet under the high temperature conditions of the reflow process described herein.

Next, referring to FIG. 11F, UV rays can be radiated onto the UV-curable adhesive sheet 400.

The UV-curable adhesive sheet 400 includes an adhesive composition having a UV-curable system, and can be cured by UV rays in the present process. As a result thereof, referring to FIG. 11G, a semiconductor package 500 cut from the cured UV-curable adhesive sheet 400 may be easily picked up. In the present embodiment, because the UV-curable adhesive sheet 400 may be significantly lowered in the present step, defects such as breakage of the semiconductor package 500 that occur when the adhesive strength remaining during the pick-up process is high may also be prevented.

As described herein, in the manufacturing method according to the present embodiment, a process of manufacturing a semiconductor package with high yield may be ensured by changing a timing of irradiating the UV-curable adhesive sheet with UV rays to after the cutting process and before the pick-up process, and enhancing chemical resistance and/or heat resistance of the adhesive composition.

As set forth herein, according to the embodiments described herein, by irradiating a UV-curable adhesive sheet with UV rays after a cutting process and before a transfer process (or pick-up process), a desired adhesive strength may be secured in the cutting process, thereby preventing defects.

In addition, an adhesive composition of the UV-curable adhesive sheet may include a monomer branched into a polymer to enhance chemical resistance and a photoinitiator with excellent thermal stability to enhance heat resistance.

The various and advantageous advantages and effects of the present inventive concept are not limited to the present description, and may be more easily understood in the course of describing the specific embodiments of the present inventive concept. While example embodiments have been shown and described herein, it will be apparent to those skilled in the art that modifications and variations could be made without departing from the scope of the present inventive concept, as defined by the appended claims.

While example embodiments have been shown and described herein, it will be apparent to those skilled in the art that modifications and variations could be made without departing from the scope of the present inventive concept.

What is claimed is:

1. A method of manufacturing a semiconductor package, comprising:
forming a bonding layer on a carrier;
forming a redistribution substrate on the bonding layer;
mounting a plurality of semiconductor chips on the redistribution substrate, thereby forming a package structure for a plurality of semiconductor packages;
bonding a UV-curable adhesive sheet to a surface of the package structure opposite the bonding layer and the redistribution substrate;
removing the carrier and the bonding layer from the package structure;
forming an under bump metallurgy (UBM) layer and forming an external connection conductor on the redistribution substrate;
cutting the package structure into the plurality of semiconductor packages;
irradiating the UV-curable adhesive sheet with UV rays, after cutting the plurality of semiconductor packages; and
separating the plurality of semiconductor packages from the UV-curable adhesive sheet.

2. The method of manufacturing a semiconductor package of claim 1, wherein the bonding layer includes a release layer on the carrier and a metal layer on the release layer.

3. The method of manufacturing a semiconductor package of claim 2, wherein the removing the carrier and the bonding layer includes separating the carrier at the release layer by applying energy to the release layer, and removing the metal layer by wet etching.

4. The method of manufacturing a semiconductor package of claim 3, wherein, before the irradiating the UV-curable adhesive sheet with UV rays, the UV-curable adhesive sheet comprises a polymer, a monomer, and a photoinitiator, the monomer including a monomer branched into the polymer.

5. The method of manufacturing a semiconductor package of claim 1, wherein the forming an external connection conductor on the redistribution substrate comprises performing a reflow process.

6. The method of manufacturing a semiconductor package of claim 5, wherein the UV-curable adhesive sheet comprises an adhesive composition comprising a polymer, a monomer and a photoinitiator, the photoinitiator having thermal stability so that 90% or more of an initial weight of the photoinitiator is maintained for 10 minutes at 200° C. or higher.

7. The method of manufacturing a semiconductor package of claim 1, wherein the UV-curable adhesive sheet comprises a base film and a UV-curable adhesive layer on the base film.

8. The method of manufacturing a semiconductor package of claim 7, wherein the base film comprises at least one material selected from the group consisting of polyether ether ketone (PEEK), polyethylene naphthalate (PEN), polyethylenimine (PEI), and aramid.

9. The method of manufacturing a semiconductor package of claim 7, wherein the UV-curable adhesive layer comprises an adhesive composition comprising an acrylic-based polymer, an acrylic-based monomer having a carbon-carbon bond, and a photoinitiator having an operating wavelength of 460 nm or less, and the acrylic-based monomer comprises a monomer branched into the acrylic-based polymer.

10. The method of manufacturing a semiconductor package of claim 9, wherein the photoinitiator has thermal stability so that 95% or more of an initial weight thereof is maintained for 10 minutes at 250° C. or higher.

11. The method of manufacturing a semiconductor package of claim 1, wherein the forming the external connection conductor comprises forming the external connection conductor on the UBM layer, and applying a reflow process to the external connection conductor, and
wherein the UV-curable adhesive sheet has a first adhesive strength before the reflow process, a second adhesive strength higher than the first adhesive strength after the reflow process and before the irradiating the UV-curable adhesive sheet with UV rays, and a third adhesive strength lower than the first adhesive strength after irradiating the UV-curable adhesive sheet with UV rays.

12. The method of manufacturing a semiconductor package of claim 1, wherein the forming the package structure includes
forming conductive posts on the redistribution substrate,
disposing a plurality of first semiconductor chips on the redistribution substrate,
forming a first encapsulant surrounding the plurality of first semiconductor chips and the conductive posts on the redistribution substrate, and
forming a redistribution structure connected to the conductive posts on the first encapsulant.

13. The method of manufacturing a semiconductor package of claim 12, wherein the forming the package structure further comprises
disposing a plurality of second semiconductor chips on the redistribution structure, and
forming a second encapsulant surrounding the second semiconductor chips on the redistribution structure.

14. A method of manufacturing a semiconductor package, comprising:
forming a bonding layer on a carrier, wherein the bonding layer includes a release layer on the carrier and a metal layer on the release layer;
forming a redistribution substrate on the bonding layer;
by mounting a plurality of semiconductor chips on the redistribution substrate, thereby forming a package structure for a plurality of semiconductor packages;
bonding a UV-curable adhesive sheet to a surface of the package structure opposite the bonding layer and the redistribution substrate, wherein the UV-curable adhesive sheet includes an adhesive composition including a polymer, a monomer, and a photoinitiator, the monomer including a monomer branched into the polymer;
separating the carrier from the package structure at the release layer by applying energy to the release layer;
removing the metal layer from the package structure by wet etching;
forming an under bump metallurgy (UBM) layer on the redistribution substrate;
forming an external connection conductor on the UBM layer, and applying a reflow process to the external connection conductor;
cutting the package structure into the plurality of semiconductor packages;
irradiating the UV-curable adhesive sheet with UV rays, after cutting the plurality of semiconductor packages; and
separating the plurality of semiconductor packages from the UV-curable adhesive sheet.

15. The method of manufacturing a semiconductor package of claim 14, wherein the adhesive composition of the UV-curable adhesive sheet further comprises an oligomer in which the monomer is cross-linked.

16. The method of manufacturing a semiconductor package of claim 14, wherein the photoinitiator has thermal stability so that 95% or more of an initial weight thereof is maintained for 10 minutes at 250° C. or higher.

17. The method of manufacturing a semiconductor package of claim 14, wherein the UV-curable adhesive sheet comprises a base film, a UV-curable adhesive layer on the base film, and an anchor layer between the base film and the UV-curable adhesive layer.

18. A method of manufacturing a semiconductor package, comprising:
forming a bonding layer on a carrier, wherein the bonding layer includes a release layer on the carrier and a metal layer on the release layer;
forming a redistribution substrate on the bonding layer;
mounting a plurality of semiconductor chips on the redistribution substrate, thereby forming a package structure for a plurality of semiconductor packages;
bonding a UV-curable adhesive sheet to a surface of the package structure opposite the bonding layer and the redistribution substrate, wherein an adhesive composition of the UV-curable adhesive sheet includes a photoinitiator having thermal stability so that 90% or more of an initial weight of the photoinitiator is maintained for 10 minutes at 200° C. or higher;
separating the carrier from the package structure at the release layer by applying energy to the release layer;
removing the metal layer from the package structure by wet etching;
forming an under bump metallurgy (UBM) layer on the redistribution substrate;
forming an external connection conductor on the UBM layer, and applying a reflow process to the external connection conductor;
cutting the package structure into the plurality of semiconductor packages;
irradiating the UV-curable adhesive sheet with UV rays, after cutting the plurality of semiconductor packages; and
separating the plurality of semiconductor packages from the UV-curable adhesive sheet,
wherein the UV-curable adhesive sheet has a first adhesive strength before the reflow process, has a second adhesive strength higher than the first adhesive strength after the reflow process and before the irradiating the UV-curable adhesive sheet with UV rays, and a third adhesive strength lower than the first adhesive strength after the irradiating the UV-curable adhesive sheet with UV rays.

19. The method of manufacturing a semiconductor package of claim 18, wherein the second adhesive strength is at least twice that of the first adhesive strength, and the third adhesive strength is at most 1/10 time that of the first adhesive strength.

20. The method of manufacturing a semiconductor package of claim 18, wherein the second adhesive strength is 2 N/inch or more, and the third adhesive strength is 1 N/inch or less.
